(19) United States
(12) Patent Application Publication
(10) Pub. No.: US 2022/0069159 A1
(43) Pub. Date: Mar. 3, 2022

(54) INTERMEDIATE STRUCTURE FOR MANUFACTURING MICRO LIGHT EMITTING DIODE DISPLAY, METHOD OF MANUFACTURING THE SAME, AND METHOD OF MANUFACTURING MICRO LED DISPLAY

(71) Applicant: SAMSUNG ELECTRONICS CO., LTD., Suwon-si (KR)

(72) Inventor: Takashi TAKAGI, Kanagawa (JP)

(73) Assignee: SAMSUNG ELECTRONICS CO., LTD., Suwon-si (KR)

(21) Appl. No.: 17/462,883

(22) Filed: Aug. 31, 2021

(30) Foreign Application Priority Data
Sep. 1, 2020 (JP) 2020-146780
May 21, 2021 (KR) 10-2021-0065282

(51) Int. Cl. H01L 33/00; H01L 25/075

(52) U.S. Cl. CPC H01L 33/0095; H01L 25/0753

(57) ABSTRACT

An intermediate structure for manufacturing a micro LED display includes a transparent substrate that is configured to allow laser light of a certain wavelength to be transmitted there through, a first resin layer arranged on the transparent substrate, a second resin layer arranged on the first resin layer, and a plurality of micro LED chips arranged on the second resin layer. The first resin layer and the second resin layer are patterned to correspond to the plurality of micro LED chips.

### CROSS-REFERENCE TO THE RELATED APPLICATIONS

This application is based on and claims priority under 35 U. S. C. § 119 to Japanese Patent Application No. 2020-146780 filed on Sep. 1, 2020, and Korean Patent Application No. 10-2021-0065282 filed on May 21, 2021, the disclosures of which are incorporated herein by reference in their entireties.

### BACKGROUND

### 1. Field

Embodiments of the present disclosure relate to an intermediate structure for manufacturing a micro light emitting diode (LED) display, a method of manufacturing the intermediate structure, and a method of manufacturing the micro LED display.

### 2. Discussion of Related Art

A display using micro light emitting diodes (LEDs) comes into the spotlight these days. The micro LED display is a next generation display that has quick responses, does not cause burn-in, and is able to output images with high brightness and high quality at low power.

When it comes to manufacturing a high-quality display with the micro LEDs, reducing the manufacturing costs is one of the biggest challenges. To reduce the costs, reducing the size of a micro LED chip is effective. Micro LED chips having a size of about 20 μm are being developed these days.

Meanwhile, to use fine micro LED chips for a display, a technology to transfer the micro LED chips to a driving circuit board from a wafer is required. In this case, the micro LED chips are transferred with a pixel pitch of the display. An example of the technology of transferring the micro LED chips is, for example, a laser transfer method.

For example, Patent Document 1 describes a method of manufacturing a micro LED display using the laser transfer method. In the patent document, a transfer board is provided to primarily hold LED chips to transfer the LED chips from a transfer source board to a transfer destination board. With this technology, a shock absorbing layer and a chip holding layer are sequentially accumulated on the transfer destination layer, and the micro LED chips are transferred from the transfer destination board onto the chip holding layer in the laser transfer method. The shock absorbing layer provided by this technology suppresses shocks from laser transferring, thereby enabling the micro LED chips to be very accurately transferred.

However, high-quality micro LED display including 4K or 8K requires more accurate transferring of numerous micro LED chips to target positions. Hence, a more accurate transfer technology is required for manufacturing the micro LED display.

### RELATED ART DOCUMENTS

### Patent Document

PATENT DOCUMENT 1: Japanese Unexamined Patent Application Publication No. 2019-67892

### SUMMARY

Embodiments of the present disclosure provide an intermediate structure for manufacturing a micro light emitting diode (LED) display, which enables very accurate transferring.

Embodiments of the present disclosure also provide a method of manufacturing an intermediate structure for manufacturing a micro LED display, which enables very accurate transferring.

Embodiments of the present disclosure also provide a method of manufacturing a micro LED display that enables very accurate transferring.

According to one or more embodiments, an intermediate structure for manufacturing a micro light emitting diode (LED) display is provided. The intermediate structure includes: a transparent substrate that is configured to allow laser light of a certain wavelength to be transmitted there through; a first resin layer arranged on the transparent substrate; a second resin layer arranged on the first resin layer; and a plurality of micro LED chips arranged on the second resin layer, wherein the first resin layer and the second resin layer are patterned to correspond to the plurality of micro LED chips.

According to an embodiment, the first resin layer and the second resin layer are configured to be oxygen plasma based dry etched.

According to an embodiment, the first resin layer is configured to be decomposed by a laser ablation treatment.

According to an embodiment, the first resin layer includes at least one resin material selected from a group consisting of a polyimide resin, an acrylic resin, an epoxy resin, a polypropylene resin, a polycarbonate resin, and an acrylonitrile butadiene styrene (ABS) resin.

According to an embodiment, the second resin layer includes a resin material having compressive modulus of about 1 to 100 Mpa.

According to an embodiment, the resin material or at least one other resin material of the second resin layer is selected from a group consisting of urethane, isoprene, and butadiene.

According to an embodiment, the transparent substrate is configured to transmit 50% or more of laser light with a wavelength of 248 to 355 nm.

According to an embodiment, the first resin layer is configured to absorb 60% or more of laser light of 248 to 355 nm.

According to an embodiment, the first resin layer has a thickness of 0.5 to 2 μm.

According to an embodiment, the second resin layer has a thickness of 1 to 10 μm.

According to an embodiment, the plurality of micro LED chips includes micro LED chips of different light emitting colors, wherein the plurality of micro LED chips are arranged on the second resin layer in a form of a matrix, and wherein each of the plurality of micro LED chips constitutes a subpixel of the micro LED display.

According to one or more embodiments, a method of manufacturing an intermediate structure for manufacturing a micro light emitting diode (LED) display is provided. The method includes: stacking a first resin layer on a transparent substrate, the transparent substrate configured to transmit laser light of a certain wavelength; stacking a second resin layer on the first resin layer; arranging a plurality of micro LED chips on the second resin layer; and patterning the first resin layer and the second resin layer to correspond to the plurality of micro LED chips.

According to an embodiment, the patterning of the first resin layer and the second resin layer includes patterning the first resin layer and the second resin layer using oxygen plasma dry etching.

According to an embodiment, the first resin layer includes at least one resin material selected from a group consisting of a polyimide resin, an acrylic resin, an epoxy resin, a polypropylene resin, a polycarbonate resin, and an acrylonitrile butadiene styrene (ABS) resin.

According to an embodiment, the second resin layer includes at least one resin material selected from a group consisting of urethane, isoprene, and butadiene.

According to an embodiment, the arranging of the plurality of micro LED chips includes arranging the plurality of micro LED chips on the second resin layer in a form of a matrix such that each of the plurality of micro LED chips forms a subpixel of the micro LED display.

According to one or more embodiments, a method of manufacturing a micro light emitting diode (LED) display is provided. The method includes manufacturing an intermediate structure by: stacking a first resin layer on a transparent substrate, the transparent substrate configured to transmit laser light of a certain wavelength; stacking a second resin layer on the first resin layer; arranging a plurality of micro LED chips on the second resin layer; and patterning the first resin layer and the second resin layer to correspond to the plurality of micro LED chips. The method further includes transferring at least one group of micro LED chips, from among the plurality of micro LED chips, from the intermediate structure to a driving circuit board of the micro LED display.

According to an embodiment, the transferring includes transferring the at least one group of micro LED chips by irradiating the laser light.

According to an embodiment, the patterning of the first resin layer and the second resin layer includes patterning the first resin layer and the second resin layer using oxygen plasma dry etching.

According to an embodiment, each micro LED chip from among the at least one group of micro LED chips forms a subpixel of the micro LED display.

### Advantageous Effects

According to embodiments of the disclosure, a plurality of micro LED chips are arranged on a laser-light transparent board on which first and second resin layers are arranged as an intermediate structure for manufacturing a micro LED display. In embodiments of the disclosure, the first and second resin layers are patterned to correspond to the plurality of micro LED chips. Using the intermediate structure according to embodiments of the disclosure, very accurate transferring is enabled in manufacturing the micro LED display.

### BRIEF DESCRIPTION OF THE DRAWINGS

The above and other objects, features, and advantages of embodiments of the present disclosure will become more apparent to those of ordinary skill in the art by describing in detail non-limiting example embodiments thereof with reference to the accompanying drawings, in which:

FIG. 1 is a cross-sectional view of micro light emitting diode (LED) chips on a sapphire substrate, according to a first embodiment of the disclosure;

FIG. 2 is a plan view illustrating arrangement of the micro LED chips on the sapphire substrate, according to the first embodiment of the disclosure;

FIG. 3 is a first cross-sectional view illustrating a manufacturing process of a donor board, according to the first embodiment of the disclosure;

FIG. 4 is a second cross-sectional view illustrating the manufacturing process of the donor board, according to the first embodiment of the disclosure;

FIG. 5 is a third cross-sectional view illustrating the manufacturing process of the donor board, according to the first embodiment of the disclosure;

FIG. 6 is a fourth cross-sectional view illustrating the manufacturing process of the donor board, according to the first embodiment of the disclosure;

FIG. 7 is a fifth cross-sectional view illustrating the manufacturing process of the donor board, according to the first embodiment of the disclosure;

FIG. 8 is a first cross-sectional view illustrating a manufacturing process of a source board, according to the first embodiment of the disclosure;

FIG. 9 is a second cross-sectional view illustrating the manufacturing process of the source board, according to the first embodiment of the disclosure;

FIG. 10 is a third cross-sectional view illustrating the manufacturing process of the source board, according to the first embodiment of the disclosure;

FIG. 11 is a fourth cross-sectional view illustrating the manufacturing process of the source board, according to the first embodiment of the disclosure;

FIG. 12 is a fifth cross-sectional view illustrating the manufacturing process of the source board, according to the first embodiment of the disclosure;

FIG. 13 is a plan view illustrating arrangement of the micro LED chips on a second resin layer, according to the first embodiment of the disclosure;

FIG. 14 is a cross-sectional view along line A-A of FIG. 13;

FIG. 15 is a cross-sectional view along line B-B of FIG. 13;

FIG. 16 is a cross-sectional view illustrating a finished source board, according to the first embodiment of the disclosure;

FIG. 17 is a cross-sectional view illustrating a driving circuit board, according to the first embodiment of the disclosure;

FIG. 18 is a cross-sectional view illustrating a transferring process of the micro LED chips from the source board onto the driving circuit board, according to the first embodiment of the disclosure;

FIG. 19 is a cross-sectional view of a display module after a second laser transfer process, according to the first embodiment of the disclosure;

FIG. 20 is a cross-sectional view illustrating a finished display module, according to the first embodiment of the disclosure;

FIG. 21 is a plan view illustrating arrangement of the micro LED chips on a display module, according to the first embodiment of the disclosure;

FIG. 22 is a schematic diagram for describing flows of a method of manufacturing a display, according to the first embodiment of the disclosure;

FIG. 23 is a schematic diagram for describing flows of a method of manufacturing the display, according to the first embodiment of the disclosure;

FIG. 24 is a schematic diagram for describing flows of a method of manufacturing a display, according to a comparative example;

FIG. 25 is a cross-sectional view of micro LED chips on a sapphire substrate, according to a second embodiment of the disclosure;

FIG. 26 is a first cross-sectional view illustrating a manufacturing process of a donor board, according to the second embodiment of the disclosure;

FIG. 27 is a second cross-sectional view illustrating the manufacturing process of the donor board, according to the second embodiment of the disclosure;

FIG. 28 is a third cross-sectional view illustrating the manufacturing process of the donor board, according to the second embodiment of the disclosure;

FIG. 29 is a fourth cross-sectional view illustrating the manufacturing process of the donor board, according to the second embodiment of the disclosure;

FIG. 30 is a first cross-sectional view illustrating a manufacturing process of a source board, according to the second embodiment of the disclosure;

FIG. 31 is a second cross-sectional view illustrating the manufacturing process of the source board, according to the second embodiment of the disclosure;

FIG. 32 is a third cross-sectional view illustrating the manufacturing process of the source board, according to the second embodiment of the disclosure;

FIG. 33 is a fourth cross-sectional view illustrating the manufacturing process of the source board, according to the second embodiment of the disclosure;

FIG. 34 is a first cross-sectional view illustrating a manufacturing process of a display module, according to the second embodiment of the disclosure;

FIG. 35 is a second cross-sectional view illustrating the manufacturing process of the display module, according to the second embodiment of the disclosure;

FIG. 36 is a third cross-sectional view illustrating the manufacturing process of the display module, according to the second embodiment of the disclosure; and

FIG. 37 is a fourth cross-sectional view illustrating a finished display module, according to the second embodiment of the disclosure.

### DETAILED DESCRIPTION

Non-limiting example embodiments of the present disclosure will now be described with reference to accompanying drawings. Like reference numerals refer to like elements in the drawings, and the elements may be exaggerated in size for clarity and convenience for explanation. Embodiments of the disclosure as will be described below are merely illustrative examples, and there may be various modifications to the embodiments of the disclosure.

The terms “top” and “above” as herein used may indicate not only an occasion when one is located right on the other but also an occasion when one is located over the other without contact.

It is to be understood that the singular forms “a,” “an,” and “the” include plural references unless the context clearly dictates otherwise. The term “include (or including)” or “comprise (or comprising)” is inclusive or open-ended and does not exclude additional, unrecited elements or method steps, unless otherwise mentioned.

Furthermore, “said”, “the”, or similar words indicate a single antecedent event or thing as well as a plurality of antecedent events or things.

Steps or operations constituting a method are performed in any suitable sequence unless there is an explicit sequence of them or otherwise mentioned. That is, embodiments of the present disclosure are not limited to the described order of the steps or operations. All examples or exemplary terms (e.g., etc.) are simply used to help describe technical ideas of embodiments of the present disclosure, and do not restrict the scope of the disclosure.

A method of manufacturing a micro light emitting diode (LED) display (hereinafter, simply referred to as a display) will now be described according to a first embodiment of the disclosure.

[Manufacturing Micro LED Chips]

In the first embodiment of the disclosure, micro LED chips are manufactured first.

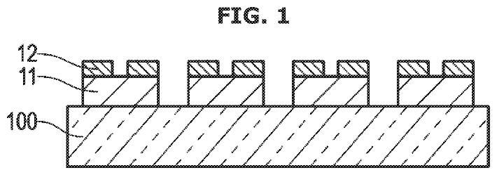

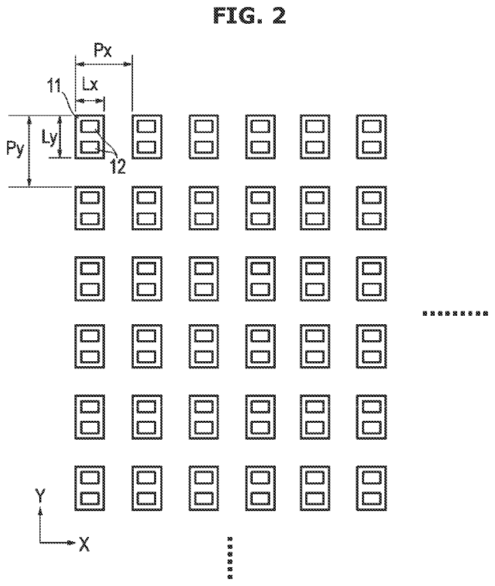

FIG. 1 is a cross-sectional view of micro LED chips on a sapphire substrate, according to the first embodiment of the disclosure. FIG. 2 is a plan view illustrating arrangement of the micro LED chips on the sapphire substrate, according to the first embodiment of the disclosure. As FIG. 2 is focused on arrangement of micro LED chips, components other than the micro LED chips and electrodes thereupon are omitted.

In the first embodiment, first, as shown in FIG. 1, micro LED chips 11 are manufactured on a sapphire substrate 100. The micro LED chips 11 are manufactured from a semiconductor layer formed on the sapphire substrate 100. The semiconductor layer is a GaN semiconductor layer for LEDs that emit light of a certain wavelength.

Electrodes are formed on the micro LED chips 11. The electrodes are called LED electrodes 12. For a material of the LED electrodes 12, at least a metal selected from a group of e.g., Au, Ag, Cu, Al, Pt, Ni, Cr, Ti, and ITO, or graphene is used, and among them, Au, AG, and CU are preferred.

Each of the micro LED chips 11, when diced, has a size of Lx×Ly, e.g., Lx×Ly=15 μm×30 μm (see FIG. 2). Pitches to a neighboring one of the micro LED chips 11 is Px×Py, e.g., Px×Py=20 μm×35 μm (see FIG. 2).

The micro LED chips 11 are manufactured by color (light emitting color) required for the display. There are red (R), green (G), and blue (B) for a common color display.

Such micro LED chips 11 may be manufactured in the existing method, but the method is not particularly limited.

[Manufacturing a Donor Board]

Subsequently, in the first embodiment of the disclosure, a donor board for temporarily holding the micro LED chips 11 is manufactured.

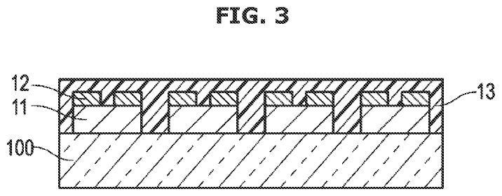

FIGS. 3 to 7 are cross-sectional views illustrating a manufacturing process of a donor board, according to the first embodiment of the disclosure.

To manufacture a donor board, first, as shown in FIG. 3, a resin layer for donor 13 is formed on the sapphire substrate 100 on which the micro LED chips 11 are formed.

The resin layer for donor 13 serves as an adhesive layer for fixing the micro LED chips 11 onto a supporting substrate 14, which will be described later.

The resin layer for donor 13 may need to be decomposed by laser light irradiation in a first laser transfer process, as will be described later. For the resin layer for donor 13, it is desirable to use a resin material having 60% to 100% absorption factor for a laser light wavelength used for a laser ablation process after the resin is hardened, and it is more desirable to use a resin material having 80% to 100% absorption factor for the laser light wavelength. Specifically, for the resin material, at least one resin selected from a group of a polyimide resin, an acrylic resin (e.g., a polymethyl methacrylate (PMMA) resin), an epoxy resin, a polypropylene (PP) resin, a polycarbonate resin, and an acrylonitrile butadiene styrene (ABS) resin is used. A thermosetting agent may be mixed with the resin to be used. Other different types of thermosetting agents may be used for the resin layer for donor 13.

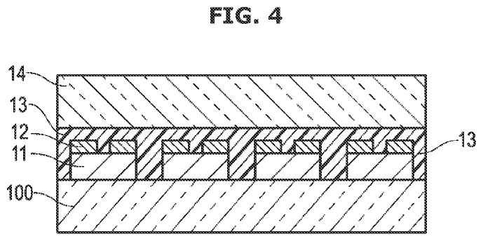

Subsequently, in manufacturing the donor board, as shown in FIG. 4, the resin layer for donor 13 is overlaid with the supporting substrate 14, and the supporting substrate 14 is bonded to the sapphire substrate 100 on a surface having the micro LED chips 11. The supporting substrate 14 transmits 50% and more of laser light, or preferably 80% and more of laser light, and uses a quartz glass substrate.

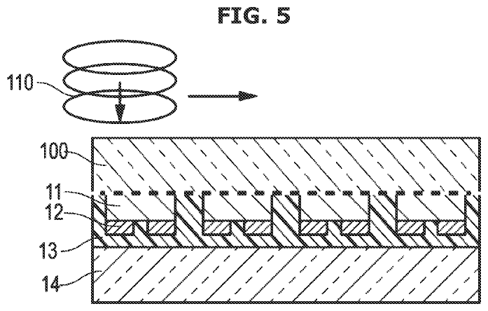

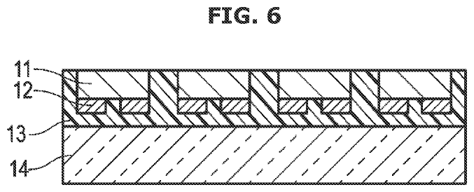

Subsequently, in manufacturing the donor board, the sapphire substrate 100 and the micro LED chips 11 are separated from each other. Separation of the micro LED chips 11 are done by a laser lift-off treatment. In the laser lift-off treatment, as shown in FIG. 5, laser light 110 is irradiated from a side of the sapphire substrate 100 toward one of the micro LED chips 11. The laser light 110 is irradiated to scan the entire surface of the sapphire substrate 100. For the laser light 110, KrF excimer laser with a wavelength of 248 nm is used. The wavelength is not limited thereto, but may be any wavelength that is able to separate the semiconductor layer from the sapphire substrate 100. The sapphire substrate 100 separated from the micro LED chips 11 is removed. The sapphire substrate 100 and the micro LED chips 11 are then separated, as shown in FIG. 6.

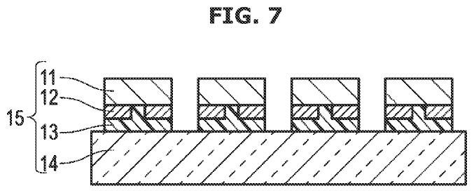

Subsequently, in manufacturing the donor board, a portion of the resin layer for donor 13 is removed. Removal of the portion of the resin layer for donor 13 is done by dry etching using oxygen plasma. The dry etching is, for example, reactive ion etching (RIE). By this dry etching process, the resin layer for donor 13 between the neighboring ones of the micro LED chips 11 is removed to form a donor board 15, as shown in FIG. 7. In this case, the resin layer for donor 13 between the supporting substrate 14 and the micro LED chips 11 is left.

The donor board 15 includes the micro LED chips 11, the LED electrodes 12, the resin layer for donor 13, and the supporting substrate 14. On the donor board 15 of the first embodiment of the disclosure, the LED electrodes 12 extends toward the supporting substrate 14.

As the resin layer for donor 13 between the neighboring ones of the micro LED chips 11 is removed from the donor board 15, accuracy in chip transfer position during laser transferring may be improved. The transfer position accuracy is represented by an amount of deviation of a transferred chip from a target position. In the first embodiment, the accuracy of the chip transfer position may be stabilized within ±5 μm.

The donor board 15 is manufactured by color required for the display. For a common color display, the donor board 15 is manufactured to correspond to red R, green G, and blue B ones of the micro LED chips 11.

Arrangement of the micro LED chips 11 on the donor board 15 is basically the same as the arrangement of the micro LED chips 11 on the sapphire substrate 100. Alternatively, arrangement of the micro LED chips 11 on the donor board 15 may be different from the arrangement of the micro LED chips 11 on the sapphire substrate 100. The number of the micro LED chips 11 held on the donor board 15 may be different from the number of the micro LED chips 11 on the sapphire substrate 100.

[Manufacturing a Source Board]

Subsequently, in the first embodiment of the disclosure, a source board for transferring the micro LED chips 11 from the donor board 15 to a driving circuit board is manufactured.

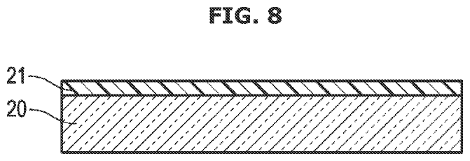

FIGS. 8 to 12 are cross-sectional views illustrating a manufacturing process of a source board, according to the first embodiment of the disclosure. In the drawings, R, G, and B indicates colors (light emitting colors) of micro LED chips 11.

To manufacture a source board, first, as shown in FIG. 8, a first resin layer 21 is formed on a laser-light transparent substrate 20, which is a base of the source board.

The laser-light transparent substrate 20 transmits the laser light 110 of a certain wavelength. The certain wavelength is a wavelength of the laser light 110 used for a laser ablation treatment as will be described later. The certain wavelength is, for example, about 248 to 355 nm. The laser-light transparent substrate 20 preferably transmits 50% or more of the laser light with the certain wavelength and more preferably, 80% or more. For this laser-light transparent substrate 20, for example, a quartz glass substrate is used.

In the first embodiment of the disclosure, the first resin layer 21 is removed by oxygen plasma dry etching in a later process. Hence, a resin material that may be decomposed and removed by the oxygen plasma dry etching is used for the first resin layer 21.

Furthermore, the first resin layer 21 may be formed with a resin material to be decomposed by the laser ablation treatment. It is desirable for the first resin layer 21 to use a resin material having 60% to 100% absorption factor of laser light, and it is more desirable to use a resin material having 80% to 100% absorption factor of the laser light.

The first resin layer may include at least one resin material selected from a group of e.g., a polyimide resin, an acrylic resin, an epoxy resin, a polypropylene resin, a polycarbonate resin, and an ABS resin. A thermosetting agent may be mixed with the resin to be used.

The first resin layer 21 may be, for example, about 0.5˜2 μm thick. The first resin layer 21 is decomposed by a laser ablation treatment while transferred to a driving circuit board as will be described later. When thickness of the first resin layer 21 is about 0.5˜2 μm, it may be easily decomposed and may not take a long process time to be removed.

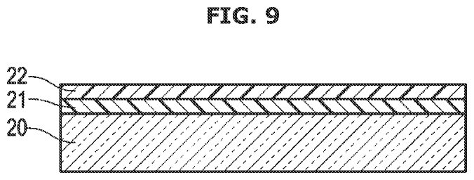

Subsequently, in manufacturing the source board, as shown in FIG. 9, a second resin layer 22 is formed on the first resin layer 21.

The second resin layer 22 is a layer to receive the micro LED chips 11 drawn out from the donor board 15 in a first laser transfer process as will be described later. The first laser transfer process is to draw out the micro LED chips 11 from the donor board 15 by the laser ablation treatment.

The second resin layer 22 may be elastic. For the second resin layer 22, it is desirable to use a resin material having compressive modulus of 1 to 100 MPa, and it is more desirable to use a resin material having compressive modulus of 5 to 30 MPa. Using the resin material having compressive modulus of 1 to 100 MPa for the second resin layer 22 helps relieve shocks when the micro LED chips 11 drawn out from the donor board 15 come into contact with the second resin layer 22. Furthermore, using the resin material having compressive modulus of 5 to 30 MPa for the second resin layer 22 may more effectively relieve the shocks.

This may contain the accuracy of transfer positions of the micro LED chips 11 within a range of about ±2 to 5 μm or less in manufacturing the source board.

Similar to the first resin layer 21, the second resin layer 22 may be formed with a resin material that may be removed by oxygen plasma dry etching.

The second resin layer 22 may include at least one resin material selected from a group of e.g., urethane, isoprene, and butadiene. For example, the second resin layer 22 is formed of an elastomer or a block copolymer having such a resin material.

The second resin layer 22 may be, for example, about 1˜10 μm thick. With this thickness of the second resin layer 22, the micro LED chips 11 drawn out by the laser ablation treatment are easily received by the second resin layer 22.

In this way, the first resin layer 21 and the second resin layer 22 are sequentially staked up on the laser-light transparent substrate 20.

Subsequently, in manufacturing the source board, the micro LED chips 11 are placed from the donor board 15 onto the second resin layer 22 on the laser-light transparent substrate 20.

Arrangement of the micro LED chips 11 from the donor board 15 onto the second resin layer 22 is done by the laser ablation treatment. This process is called a first laser transfer process.

In the first laser transfer process, the micro LED chips 11 of each color are transferred onto the second resin layer 22 from the R, G, and B ones of a plurality of the donor board 15.

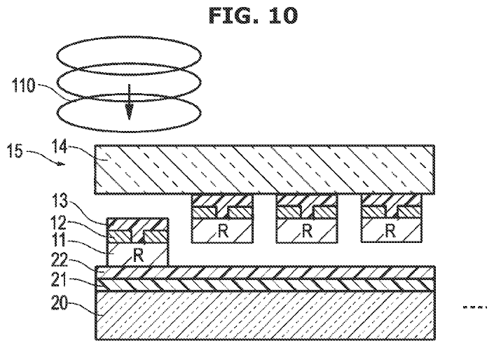

In the first laser transfer process, first, as shown in FIG. 10, for example, the donor board 15 holding the micro LED chips 11, that are R micro LED chips, is aligned to be in a desirable position over the second resin layer 22. And then, the laser light 110 is irradiated toward a single one of the micro LED chips 11 from a side of the donor board 15 settled in the position, in the first laser transfer process. For the laser light 110, KrF excimer laser with a wavelength of 248 nm is used. The wavelength is not limited thereto as long as it is able to separate the micro LED chips 11 from the supporting substrate 14.

As such, one of the micro LED chips 11 held on the donor board 15 is drawn out onto the second resin layer 22.

In the first laser transfer process, all the R micro LED chips are transferred in desirable positions on the second resin layer 22 from the donor board 15 holding the R micro LED chips. After all the R micro LED chips are transferred, the micro LED chips 11 of a next color are moved for transferring.

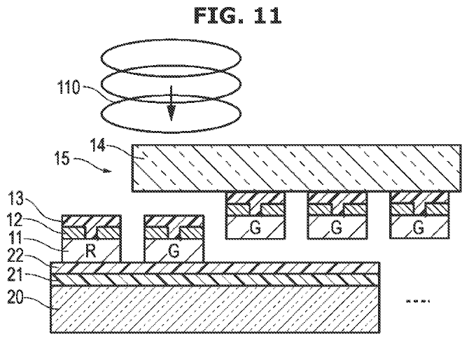

For example, when the next color is G, in the first laser transfer process, as shown in FIG. 11, the donor board 15 holding the micro LED chips 11, that are G micro LED chips, is aligned to be in a desirable position over the second resin layer 22. Similar to the R chips, the G micro LED chips are transferred onto the second resin layer 22 from the donor board 15 by the laser ablation treatment. After all the G micro LED chips are transferred to be in desirable positions on the second resin layer 22, the micro LED chips 11 of a next color are moved for transferring.

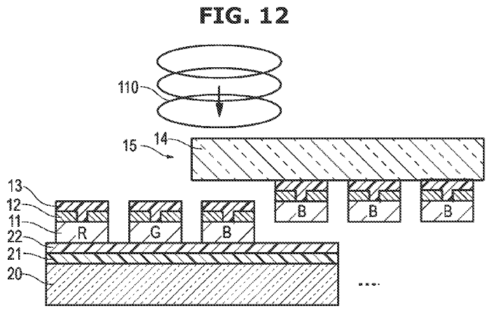

For example, when the next color is B, in the first laser transfer process, as shown in FIG. 12, the donor board 15 holding the micro LED chips 11, that are B micro LED chips, is aligned to be in a desirable position over the second resin layer 22. Similar to the R or G chips, the B micro LED chips are transferred onto the second resin layer 22 from the donor board 15 by the laser ablation treatment.

By doing this, in the first laser transfer process, all of the micro LED chips 11 are transferred onto the second resin layer 22 from the donor board 15 of the respective colors.

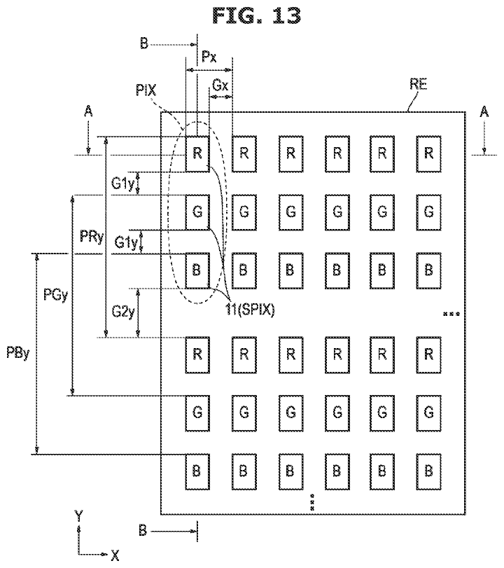

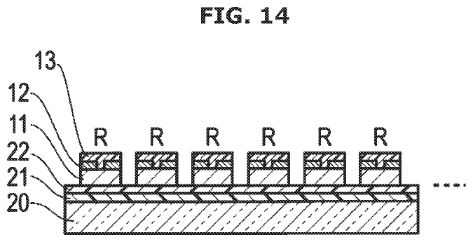

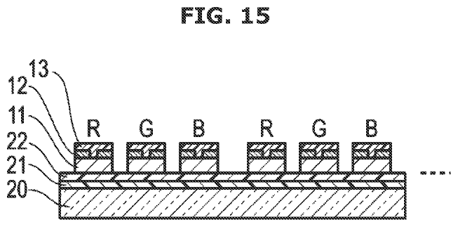

FIG. 13 is a plan view illustrating arrangement of the micro LED chips on a second resin layer, according to the first embodiment of the disclosure. FIG. 14 is a cross-sectional view along line A-A of FIG. 13. FIG. 15 is a cross-sectional view along line B-B of FIG. 13. As FIG. 13 is focused on arrangement of the micro LED chips 11, components other than the micro LED chips 11 are omitted.

On the second resin layer 22, of the plurality of micro LED chips 11, the micro LED chips 11 of the same color are arranged in an X direction at certain intervals Gx and the micro LED chips 11 of different colors are arranged in a Y direction at certain intervals G1y and G2y, as shown in FIG. 13. Furthermore, the plurality of micro LED chips 11 are arranged into a rectangular form or a square form on the second resin layer 22 of the laser-light transparent substrate 20.

When a quartz glass substrate is used for the laser-light transparent substrate 20, the laser-light transparent substrate 20 has various plane forms. The quarts glass substrate may have not only the form of a rectangle or square but also the form of a circle (including a case that there is a straight portion or a cutout portion).

In the meantime, the form of the plane of the display commonly corresponds to a rectangle or a square. Accordingly, a plurality of pixels PIX of the display are also arranged in the form of a rectangle or a square.

In manufacturing the display, the micro LED chips 11 are transferred onto a driving circuit board, which will be described later, in a second laser transfer process as will be described later. Like the display, the driving circuit board has the form of a rectangle or a square. In the second laser transfer process, the micro LED chips 11 are required to be in suitable positions corresponding to electrodes, which will be described later, on the driving circuit board.

In the first embodiment of the disclosure, a region RE, which may be rectangular or square, is set up on the second resin layer 22 of the laser-light transparent substrate 20 and the plurality of micro LED chips 11 are arranged in the rectangular form or square form in the region RE.

Accordingly, in the first embodiment of the disclosure, the number of times of position determination may be reduced during the second laser transfer process. For example, assuming that two perpendicular sides of the rectangular form or square form are in X and Y directions, respectively, position determination is made such that a positions in the X direction is first determined and fixed, and then determination of a position in the Y direction and laser transferring are sequentially performed until the micro LED chips 11 arranged in the Y direction are not left. After this, determination of a position in the X direction, determination of positions in the Y direction, and laser transferring are sequentially performed. In this case, the more the number of micro LED chips 11 arranged in the Y direction, the less the operation of determining positions in the X direction. Determination of positions in the X and Y directions may be made in the reverse order.

As such, to arrange the micro LED chips 11 on a rectangular or square driving circuit board, forming the micro LED chips 11 into a rectangular or square shape may lessen the operation of determining the positions, thereby reducing a time (tag time) required for the second laser transfer process.

A pitch Px to a neighboring one of the micro LED chips 11 in the X direction is Px=20 μm. A gap Gx between neighboring ones of the micro LED chips 11 in the X direction is Gx=5 μm.

It is desirable that the gap (Gx) between the neighboring ones of the micro LED chips 11 in the X direction is made as narrow as possible. As the gap Gx is narrower, many micro LED chips 11 may be mounted on the laser-light transparent substrate 20.

However, when the gap Gx is too narrow, an adjacent one of the micro LED chips 11 in the X direction might be mistakenly drawn out when a target one of the micro LED chips 11 is being drawn out by the laser light in the second laser transfer process. Hence, it is desirable to adjust the gap Gx not to be too narrow by taking into account the size of a laser spot in the X direction. The gap Gx is not limited to 5 μm, but may have a smaller or larger value than 5 μm.

The micro LED chips 11 are repeatedly arranged in the order of R, G, and B in a certain direction. The certain direction corresponds to the Y direction. In the Y direction, a set of the R, G, and B micro LED chips 11 constitutes a pixel PIX on the display. Each of the R, G, and B ones of the micro LED chips 11 constitutes a subpixel SPIX on the display.

In the certain direction (the Y direction in this embodiment), a gap between the micro LED chips 11 in one pixel PIX, i.e., a first gap G1y, is 10 μm, i.e., G1y=10 μm. The first gap G1y is set by taking into account the size of one pixel PIX on the display. For example, the first gap G1y on the second resin layer 22 is set to be equal to a gap between subpixels SPIX constituting a pixel PIX of the display.

In the certain direction (the Y direction in this embodiment), a gap between neighboring ones of the micro LED chips 11 that do not both belong to a same pixel PIX, i.e., a second gap G2y, is 20 μm, i.e., G2y=20 μm.

The second gap G2y may be adjusted by taking into account the size of a laser spot in the Y direction in the second laser transfer process. In the second laser transfer process, three of the micro LED chips 11 are gathered and subject to laser irradiation to be drawn out. Hence, it is desirable to adjust the second gap G2y to prevent the laser spot from reaching one of the micro LED chips 11 of a neighboring one of the pixel PIX. The second gap G2y is not limited to 20 μm, but may have a smaller or larger value than 20 μm. For example, the second gap G2y may be equal to the first gap G1y or the gap Gx in the X direction.

With these gaps, pitches Pry, Pgy, and Pby to the micro LED chips 11 of the same color between neighboring ones of the pixel PIX are, for example, 130 μm, i.e., Pry=Pgy=Pby=130 μm.

After the first laser transfer process, as shown in FIGS. 14 and 15, the resin layer for donor 13 is left on the micro LED chips 11 and the LED electrodes 12. The first resin layer 21 and the second resin layer 22 are arranged on almost the whole surface of the laser-light transparent substrate 20. The second resin layer 22 is exposed in regions between neighboring ones of the micro LED chips 11.

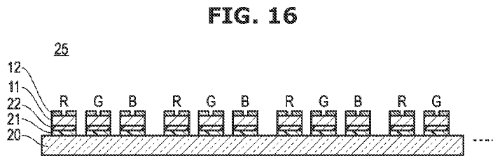

Subsequently, in manufacturing the source board, the first resin layer 21 and the second resin layer 22 are patterned at the same time when the resin layer for donor 13 is removed. As a result, the source board is formed (see a source board 25 in FIG. 16). For removal of the resin layer for donor 13 and patterning of the first resin layer 21 and the second resin layer 22, for example, oxygen plasma dry etching is used. For the dry etching, for example, RIE may be used. By this dry etching, the second resin layer 22 and the first resin layer 21 between neighboring ones of the micro LED chips 11 are removed so that the first resin layer 21 and the second resin layer 22 are patterned.

FIG. 16 is a cross-sectional view illustrating a finished source board, according to the first embodiment of the disclosure. FIG. 16 shows a cross-section along line B-B of FIG. 13.

In the first embodiment, as shown in FIG. 16, the source board 25 includes the laser-light transparent substrate 20, the first resin layer 21, the second resin layer 22, the micro LED chips 11 of the respective colors, and the LED electrodes 12 on the micro LED chips 11 of the respective colors.

The number of the micro LED chips 11 held on the source board 25 corresponds to the number of the micro LED chips 11 arranged on a display module (which will be described later) for manufacturing a display. Assuming that the number of the micro LED chips 11 required for a single display module is M, the number of the micro LED chips 11 to be kept on the source board 25 may be M×N, where N≥2. In other words, in the first embodiment of the disclosure, a number of micro LED chips 11 corresponding to two or more display modules are kept on a sheet of the source board 25.

Details thereof will be described later in connection with an effect of reducing the manufacturing time, but in manufacturing the display module, the source board 25 to be loaded in a treatment device may need to be replaced.

For example, assuming that N=2, two display modules may be manufactured from a sheet of source board 25. In this case, the two display modules may be manufactured without a need for replacing the source board 25. When it is assumed that N=3, three display modules may be manufactured from a sheet of the source board 25. In this case where N=3, the three display modules may be manufactured without a need for replacing the source board 25.

As such, the number of times of replacing the source board 25 may be reduced the larger the value of N, so the time (tag time) required to manufacture the display may be shortened.

Moreover, the value of N may not be an integer, for example, N=2.5. Assuming that N=2.5, five display modules may be manufactured by replacing the source board 25 two times.

When N<2, only one display module is manufactured from a sheet of the source board 25, so there is no effect of reducing the number of times of replacing the source board 25.

As such, in the first embodiment of the disclosure, a number of micro LED chips 11 corresponding to two or more display modules are kept on a sheet of the source board 25, thereby reducing a time (tag time) to manufacture the display.

The source board 25 completed as described above is provided as an intermediate structure for manufacturing a micro LED display.

[Manufacturing a Display Module]

The recently released display products have a size of 80, 100, or more inches. A display employing micro LEDs is suitable for these large display products.

Such a large display is manufactured by manufacturing a plurality of display modules and connecting the plurality of display modules into a display panel.

That is, in the first embodiment of the disclosure, the display is manufactured in modules.

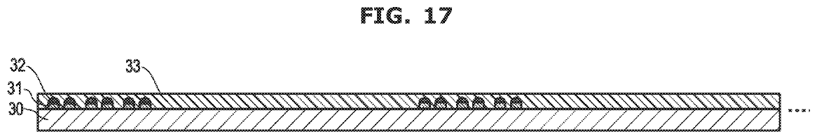

FIG. 17 is a cross-sectional view illustrating a driving circuit board, according to the first embodiment of the disclosure.

In manufacturing a display module, a driving circuit board 30 is prepared first.

The driving circuit board 30 has a size corresponding to the size of a single display module. Wiring or thin-film transistors (TFTs) and electrodes required to supply power to the micro LED chips 11 are formed on the driving circuit board 30. In the first embodiment of the disclosure, the electrodes provided on the driving circuit board 30 are called driving board electrodes 31.

The driving board electrodes 31 may be part of metal wiring, or metal pads connected to the wiring. For the driving board electrodes 31, the same metal as the aforementioned LED electrodes 12 is used.

Micro solder bumps 32 are formed on the driving board electrodes 31. The micro solder bumps 32 are formed of, for example, Ni 0.5 μm/SAC (SnAgCu, Ag 3%, Cu 0.5%) 1 μm.

Flux 33 is applied onto the driving circuit board 30 on which the micro solder bumps 32 are formed. Thickness of the flux 33 is about e.g. 10 μm.

Subsequently, in manufacturing the display module, the micro LED chips 11 are transferred from the source board 25 onto the driving circuit board 30.

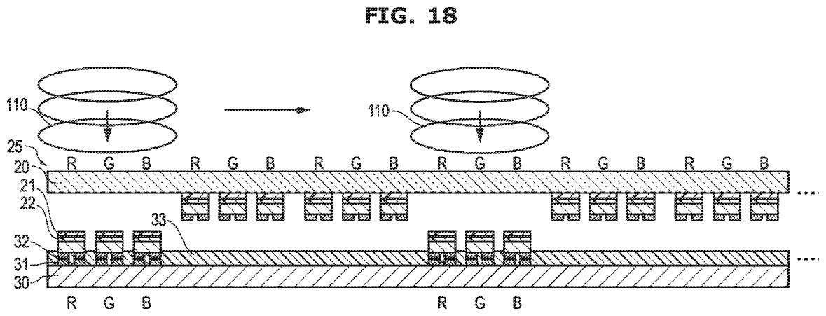

FIG. 18 is a cross-sectional view illustrating a transferring process of micro LED chips from the source board onto the driving circuit board, according to the first embodiment of the disclosure. FIG. 18 shows a cross-section in the same direction as the cross-section along line B-B of FIG. 13. For example, the laser ablation treatment is also used in this transferring process. In the first embodiment of the disclosure, this transferring process is called a second laser transfer process.

In the second laser transfer process, first, the source board 25 is located in a certain position for the driving circuit board 30 (position is determined). The certain position is where the LED electrodes 12 of the micro LED chips 11 may be connected to the driving board electrodes 31.

And then, the laser light 110 of a certain wavelength is irradiated toward three R, G, and B micro LED chips 11 from a side of the source board 25 after the position is determined, in the second laser transfer process. The certain wavelength is, for example, about 248 to 355 nm. Specifically, for example, KrF excimer laser with a wavelength of 248 nm, YAG (FHG) laser with a wavelength of 266 nm, or YAG (THG) laser with a wavelength of 355 nm is used.

In the second laser transfer process, the three micro LED chips 11 are transferred onto the driving circuit board 30 from the source board 25 by irradiation of the laser light 110 of one degree. After this, in the second laser transfer process, the position determination and laser irradiation are repeated until as many micro LED chips 11 as required for a single display module are transferred onto the driving circuit board 30.

As described above, the micro LED chips 11 on the source board 25 are fixed by the first resin layer 21 and the second resin layer 22 to the laser-light transparent substrate 20. The first resin layer 21 and the second resin layer 22, however, are separated to correspond to each of the micro LED chips 11. Accordingly, in the second laser transfer process, the micro LED chips 11 arranged on the source board 25 with high accuracy in transfer position may be drawn out to the driving circuit board 30 while keeping in their positions. This may enable the accuracy in transfer position of the micro LED chips 11 transferred onto the driving circuit board 30 to be within ±5 μm, thereby transferring the micro LED chips very accurately, in the first embodiment of the disclosure.

In a case where the first resin layer 21 and the second resin layer 22 are not patterned, the resin layer that is not decomposed by the laser light during laser irradiation remains under the diagonal of the micro LED chips 11. Hence, when the first resin layer 21 and the second resin layer 22 are not patterned, the micro LED chips 11 may be caught by the remaining resin layer and the direction of being drawn out might deviate. However, in the first embodiment of the disclosure as described above, disturbance of the direction of being drawn out hardly occurs during the laser transfer, so the micro LED chips 11 may be very accurately transferred.

After this, in the second laser transfer process, after a certain number of micro LED chips 11 are transferred onto the driving circuit board 30, other ones of the micro LED chips 11 are then transferred onto another one of the driving circuit board 30.

The driving circuit board 30 onto which the micro LED chips 11 are transferred is then heated. Accordingly, the flux 33 is volatilized and at the same time, the micro solder bumps 32 are melted to form metal bonding between the LED electrodes 12 and the driving board electrodes 31. For the heating method, for example, a reflow oven, a nitrogen flow oven, a nitrogen flow hotplate, or laser soldering is used.

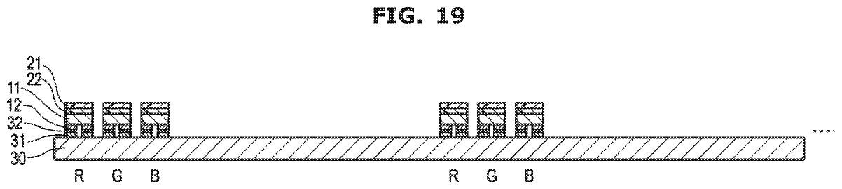

FIG. 19 is a cross-sectional view of a display module after a second laser transferring process, according to the first embodiment of the disclosure.

Referring to FIG. 19, after the second laser transfer process, the first resin layer 21 and the second resin layer 22 remain on the micro LED chips 11.

Therefore, to manufacture a display module, oxygen plasma dry etching is finally performed to remove the first resin layer 21 and the second resin layer 22. The finished display module is then cleansed.

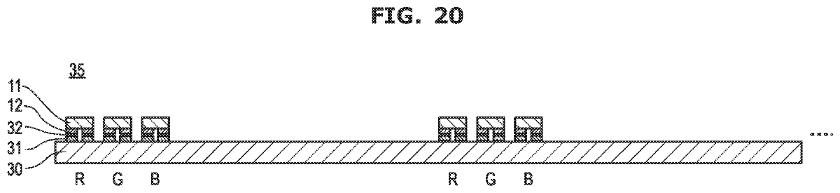

FIG. 20 is a cross-sectional view illustrating a finished display module, according to the first embodiment of the disclosure.

The display module 35 is completed after the micro LED chips 11 are bonded with the driving circuit board 30 and the first resin layer 21 and the second resin layer 22 are removed.

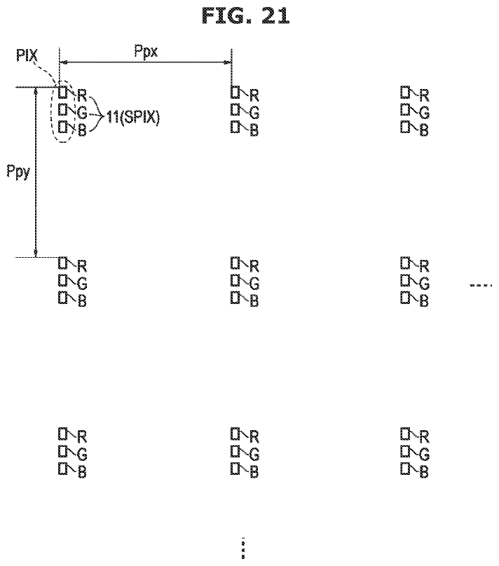

FIG. 21 is a plan view illustrating arrangement of the micro LED chips on the single display module 35, according to the first embodiment of the disclosure. As FIG. 21 is focues on arrangement of the micro LED chips 11, components other than the micro LED chips 11 are omitted.

As described above, the micro LED chips 11 arranged on the driving circuit board 30 constitute pixels PIX of the display, each pixel having three of the micro LED chips 11 having different colors. For example, the micro LED chips 11 on the driving circuit board 30 are arranged to have pitches Ppx×Ppy=520 μm×520 μm between pixels PIX.

In this way, in the first embodiment of the disclosure, a display module is manufactured from a source board 25 on which the micro LED chips 11 are arranged with high density, and the chips are more sparsely arranged on the display module than in the source board 25. Accordingly, in the embodiment of the disclosure, a manufacturing time (tag time) required to manufacture a plurality of display modules in particular may be reduced.

[Effect of Reducing a Manufacturing Time]

Effects of reducing a manufacturing time will now be described in detail.

In the first embodiment of the disclosure, a method of manufacturing a display uses a laser ablation treatment. For the laser ablation treatment, a board to be treated is loaded into a treatment room, and after the treatment is finished, the board is taken out (unloaded) from the treatment room.

Hereinafter, effects of reducing a manufacturing time will be described along with flows of a method of manufacturing a display based on the laser ablation treatment. Details of each process are the same as described above.

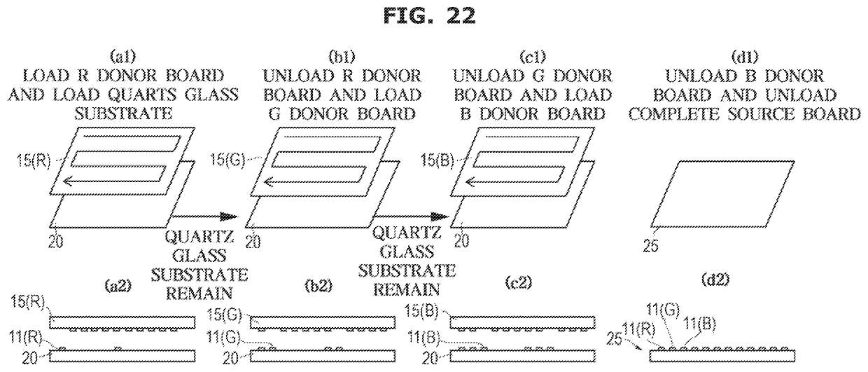

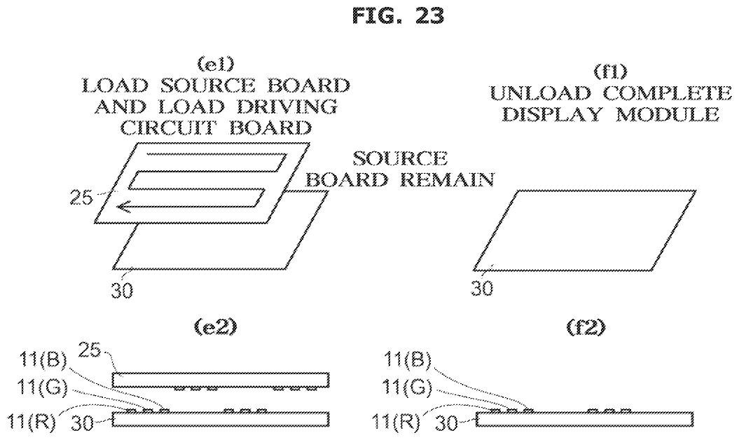

FIGS. 22 and 23 are schematic diagrams for describing flows of a method of manufacturing the display, according to the first embodiment of the disclosure. In the drawings, (a1), (b1), (c1), and (d1) are schematic perspective views, and (a2), (b2), (c2), and (d2) are schematic side views.

In the method of manufacturing a display according to the first embodiment of the disclosure, as described above, the source board 25, which is an intermediate structure, is manufactured through manufacturing of the micro LED chips 11 and manufacturing of the donor board 15.

In the method of manufacturing the display, after a plurality of the donor board 15 (including an R donor board 15(R), a G donor board 15(G), and a B donor board 15(B)) is manufactured, as shown in (a1) and (a2) of FIG. 22, the R donor board 15(R) and a laser-light transparent substrate 20, that is a base of the source board 25, are loaded into the treatment room. In the treatment room, the R micro LED chip 11(R) is transferred onto the laser-light transparent substrate 20 from the donor board 15. In this case, all the micro LED chips 11 are basically supposed to be transferred from the donor board 15(R), but not all but a certain number of micro LED chips 11 may be transferred from the donor board 15(R) (this is true for the following description).

Subsequently, as shown in (b1) and (b2) of FIG. 22, the R donor board 15(R) is unloaded and the G donor board 15(G) is loaded. The laser-light transparent substrate 20 is kept in the treatment room. In the treatment room, the G micro LED chip 11(G) is transferred onto the laser-light transparent substrate 20 from the donor board 15(G).

Subsequently, as shown in (c1) and (c2) of FIG. 22, the G donor board 15(G) is unloaded and the B donor board 15(B) is loaded. The laser-light transparent substrate 20 is kept in the treatment room. In the treatment room, the B micro LED chip 11(B) is transferred onto the laser-light transparent substrate 20 from the donor board 15(B).

Subsequently, as shown in (d1) and (d2) of FIG. 22, the source board 25 completed with the micro LED chips 11 of respective colors held on the laser-light transparent substrate 20 is unloaded.

In manufacturing the source board 25, the number of replacement times of each board (loading and unloading are counted as one time) in the treatment room is a total of 4: one time of loading and unloading of the laser-light transparent substrate 20, which is a base of the source board 25, and three times of loading and unloading of the respective colors of the donor boards 15(R), 15(G), and 15(B).

In manufacturing a plurality of display modules, the number of replacement times of each board in the treatment room is not changed from four times when the number of micro LED chips 11 held on each board corresponds to the number of display modules to be manufactured. For example, in a case of manufacturing 64 display modules, each board holds a corresponding number of micro LED chips 11. Accordingly, in manufacturing the source board 25, the number of replacement times of each board in the treatment room is four.

In the method of manufacturing a display according to the first embodiment of the disclosure, the source board 25 is manufactured and a display module is manufactured in succession.

As shown in (e1) and (e2) of FIG. 23, the source board 25 and the driving circuit board 30, before transferring and corresponding to a display module, are loaded into a treatment room. In the treatment room, a display module is completed when as many micro LED chips 11 as required for a display module are transferred onto the driving circuit board 30 from the source board 25.

Subsequently, as shown (f1) and (f2) of FIG. 23, the source board 25 is kept in the treatment room, and the completed display module is unloaded.

In a case of making a plurality of display modules, the driving circuit board 30 before transferring, which corresponds to another display module, is loaded in succession, and the other display module is manufactured by transferring the micro LED chips 11 onto the driving circuit board 30.

When manufacturing of a planned number of display modules is completed, the source board 25 is also unloaded.

In manufacturing the display module, for the treatment room, the number of replacement times of each board (loading and unloading are counted as one time) is a total of 2: one time of loading the source board 25 and then unloading the source board 25 after completion of the planned number of display modules, and one time of loading the driving circuit board 30 and unloading the completed display module.

In a case of manufacturing a plurality of display modules, the number of replace times of each board in the treatment room is obtained by adding one time of replacing the source board 25 to the number of the plurality of display modules. For example, in a case of manufacturing 64 display modules, the number of replacement times of each board in the treatment room is 64+1=65.

A time taken for a laser ablation treatment in a case of manufacturing 64 display modules according to the first embodiment of the disclosure is, for example, 63 minutes.

To help understand the embodiment of the disclosure, a comparative example will now be described. In this comparative example, a display module is manufactured directly from the donor board without manufacturing the source board 25.

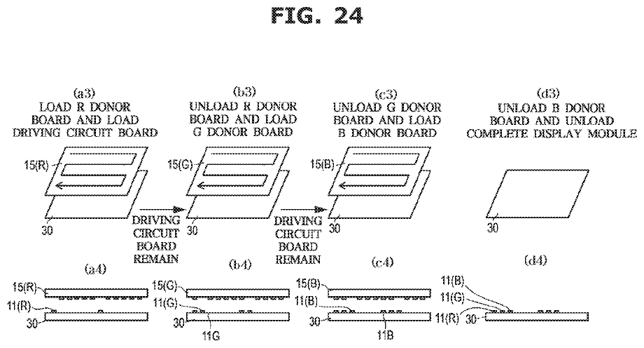

This will also be described based on the laser ablation treatment. FIG. 24 is a schematic diagram for describing flows of a method of manufacturing a display, according to a comparative example. In the drawing, (a3), (b3), (c3), and (d3) are schematic perspective views and (a4), (b4), (c4), and (d4) are schematic side views.

In the method of manufacturing a display in the comparative example, the micro LED chips 11(R), 11(G), and 11(B) are manufactured first, and then the donor board 15 is manufactured. On the plurality of the donor board 15 in the comparative example, the LED electrodes 12 on the micro LED chips 11 are exposed.

After the plurality of the donor board 15 is manufactured, as shown in (a3) and (a4) of FIG. 24, the R donor board 15(R) and the driving circuit board 30 are loaded into a treatment room. In the treatment room, the R micro LED chip 11 is transferred onto the driving circuit board 30 from the donor board 15(R). In this case, the R micro LED chip 11(R) is transferred into a certain position on the driving circuit board 30 required as a display module. This is also true for different colors of micro LED chips 11.

Subsequently, as shown in (b3) and (b4) of FIG. 24, the R donor board 15(R) is unloaded from the treatment room and the G donor board 15(G) is loaded into the treatment room. The driving circuit board 30 is kept in the treatment room. In the treatment room, the G micro LED chip 11(G) is transferred onto the driving circuit board 30 from the donor board 15(G).

Subsequently, as shown in (c3) and (c4) of FIG. 24, the G donor board 15(G) is unloaded from the treatment room and the B donor board 15(B) is loaded into the treatment room. The driving circuit board 30 is kept in the treatment room. In the treatment room, the B micro LED chip 11(B) is transferred onto the driving circuit board 30 from the donor board 15(B).

Subsequently, as shown (d3) and (d4) of FIG. 24, the B donor board 15(B) is unloaded from the treatment room, and the completed display module is unloaded.

In the comparative example, to manufacture a piece of display module, the number of replacement times of each board in the treatment room (loading and unloading are counted as one time) is a total of 4: three times of loading and unloading of the different colors of the plurality of the donor board 15 and one time of loading the driving circuit board 30 and unloading the completed display module.

In a case of manufacturing a plurality of display modules, however, in the comparative example, the number of replacement times of each board in the treatment room is counted by loading a new driving circuit board 30 after a piece of display module is completed, loading, transferring, and unloading each color of donor board. Accordingly, in the case of manufacturing a plurality of display modules in the comparative example, the number of replacement times of each board in the treatment room corresponds to the number of the plurality of display modules multiplied by 4. For example, in a case of manufacturing 64 display modules, the number of replacement times of each board in the treatment room is 64×4=256. In actual manufacturing, however, when the driving circuit board 30 in the treatment room is replaced, the plurality of the donor board 15 for different colors may be sequentially loaded while a last one of the plurality of the donor board 15 is left in the treatment room. In this case, the number of replacement times of each board in the treatment room is 192. A time taken for a laser ablation treatment in a case of manufacturing 64 display modules according to the comparative example is, for example, 166 minutes.

Compared with the comparative example, the first embodiment of the disclosure may reduce the number of replacement times of each board in the laser ablation treatment the larger the number of display modules to be manufactured is. This leads to significant reduction in manufacturing time in a method of manufacturing a display which often uses the laser ablation treatment.

In a second embodiment of the disclosure, the LED electrodes 12 on the micro LED chips 11 held on the source board 25 are not exposed. In the following description, the same components and members as in the first embodiment of the disclosure are denoted by the same reference numerals and descriptions thereof will be omitted.

[Manufacturing Micro LED Chips]

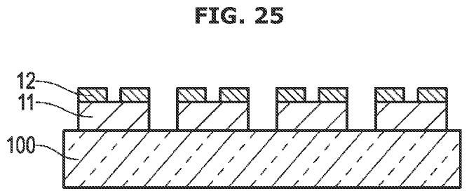

FIG. 25 is a cross-sectional view of micro LED chips on a sapphire substrate, according to a second embodiment of the disclosure.

Also in the second embodiment of the disclosure, first, as shown in FIG. 25, the micro LED chips 11 are manufactured on the sapphire substrate 100.

[Manufacturing a Donor Board]

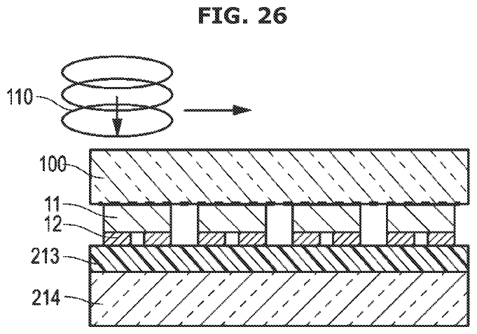

FIGS. 26 to 29 are cross-sectional views illustrating a manufacturing process of a donor board, according to the second embodiment of the disclosure.

To manufacture a donor board according to the second embodiment of the disclosure, as shown in FIG. 26, a temporary holding layer 213 is formed on a relay substrate 214 first, and then the micro LED chips 11 are transferred onto the temporary holding layer 213 from the sapphire substrate 100.

The relay substrate 214 is, for example, a quartz glass substrate, and the temporary holding layer 213 is, for example, silicon rubber such as polydimethylsiloxane (PDMS). The micro LED chips 11 are transferred by laser lift-off of the micro LED chips 11 pressed onto the temporary holding layer 213. During the laser lift-off, the laser light 110 is irradiated from a side of the sapphire substrate 100 to scan the entire surface of the sapphire substrate 100. The sapphire substrate 100 and the micro LED chips 11 are then separated from each other.

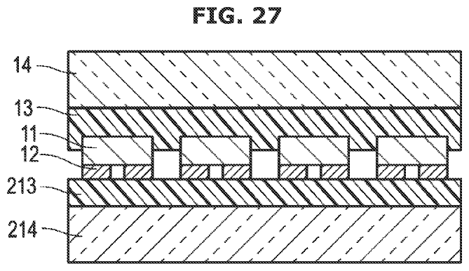

Subsequently, in the second embodiment of the disclosure, the supporting substrate 14 on which the resin layer for donor 13 is formed is prepared, and as shown in FIG. 27, the micro LED chips 11 held on the relay substrate 214 are pressed onto the resin layer for donor 13. The resin layer for donor 13 is the same as in the first embodiment of the disclosure.

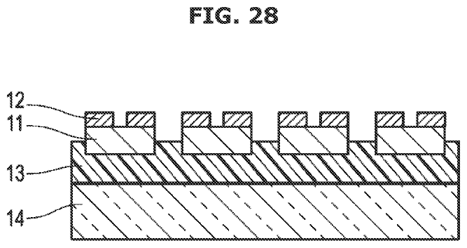

Subsequently, in the second embodiment of the disclosure, as shown in FIG. 28, the relay substrate 214 is peeled off. Accordingly, the micro LED chips 11 are separated from the temporary holding layer 213 and then held on the resin layer for donor 13. The adhesive force between the temporary holding layer 213, e.g., PDMS, and the micro LED chips 11 is sufficiently smaller than the adhesive force between the resin layer for donor 13 and the micro LED chips 11. Accordingly, in the second embodiment of the disclosure, the relay substrate 214 may be peeled off from the micro LED chips 11 for each temporary holding layer 213.

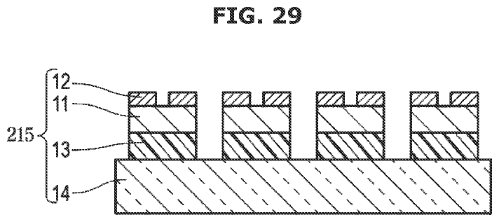

Subsequently, in the second embodiment of the disclosure, as shown in FIG. 29, the resin layer for donor 13 present between chips is removed by oxygen plasma dry etching. A board as shown in FIG. 29 is the donor board 215. On the donor board 215 of the second embodiment of the disclosure, the LED electrodes 12 are exposed.

[Manufacturing a Source Board]

Subsequently, in the second embodiment of the disclosure, the source board 325 is manufactured. A method of manufacturing the source board 325 in the second embodiment of the disclosure is basically the same as the source board 25 in the first embodiment of the disclosure except that the micro LED chips 11 have a different orientation.

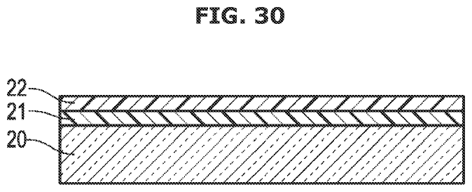

FIGS. 30 to 33 are cross-sectional views illustrating a manufacturing process of a source board, according to the second embodiment of the disclosure.

To manufacture a source board in the second embodiment of the disclosure, first, as shown in FIG. 30, the first resin layer 21 and the second resin layer 22 are formed on the laser-light transparent substrate 20, which is a base of the source board 325. Also in the second embodiment of the disclosure, e.g., a quartz glass substrate is used as the base of the source board 325 as in the first embodiment of the disclosure.

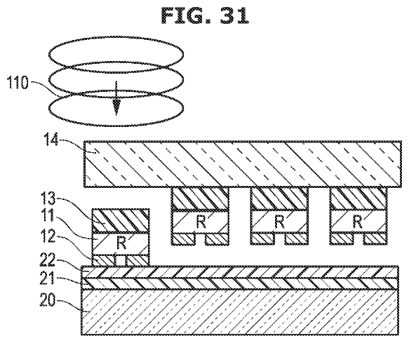

Subsequently, in the second embodiment of the disclosure, as shown in FIG. 31, the micro LED chips 11 of each color are transferred onto the laser-light transparent substrate 20 from a respective one of the donor board 215 of color by using the laser ablation treatment. FIG. 31 illustrates transferring from one of the donor board 215 that is an R donor board. This also similarly applied transferring from others of the donor board 215 that are G and B donor boards.

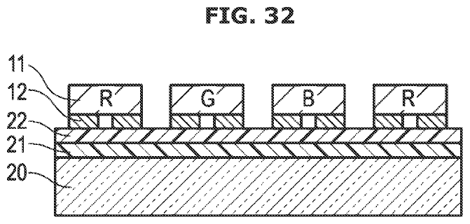

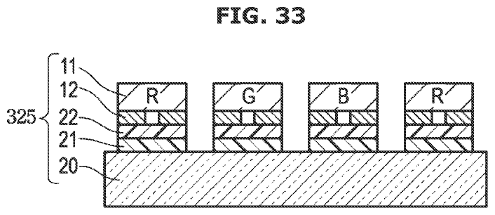

As shown in FIG. 32, the micro LED chips 11 of all colors are transferred onto the laser-light transparent substrate 20, and then, as shown in FIG. 33, the resin layer for donor 13 on the chips, and the first resin layer 21 and the second resin layer 22 between the chips are removed by oxygen plasma dry etching. The dry etching is, for example, RIE.

As a result, the source board 325 of the second embodiment of the disclosure is completed. On the source board 325 of the second embodiment of the disclosure, the LED electrodes 12 are directed toward the laser-light transparent substrate 20. The source board 325 is provided as an intermediate structure for manufacturing a micro LED display.

[Manufacturing a Display Module]

Subsequently, in the second embodiment of the disclosure, a display module is manufactured using the completed source board 325.

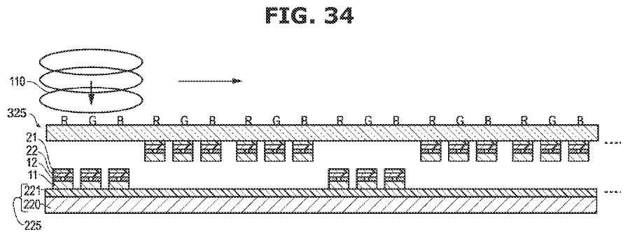

FIGS. 34 to 37 are cross-sectional views illustrating a manufacturing process of a display module, according to the second embodiment of the disclosure.

In the second embodiment of the disclosure, for example, the micro LED chips 11 of different colors are collectively transferred onto the driving circuit board 30.

For this, in the second embodiment of the disclosure, as shown in FIG. 34, the micro LED chips 11 are transferred onto the temporary holding board 225 from the source board 325 by using the laser ablation treatment. The temporary holding board 225 has a temporary holding layer 221 on the quartz glass substrate 220. The temporary holding layer 221 is, for example, PDMS. The temporary holding layer 221 is, for example, about 1 to 10 μm thick.

Arrangement of the micro LED chips 11 on the temporary holding board 225 is the same as the arrangement of the micro LED chips 11 on the display module. The arrangement of the micro LED chips 11 on the display module according to the second embodiment of the disclosure is also the same as in the first embodiment of the disclosure.

Subsequently, in the second embodiment of the disclosure, a dry etching treatment based on oxygen plasma is performed to remove the first resin layer 21 and the second resin layer 22 left on the LED electrodes 12 on the micro LED chips 11.

The driving circuit board 30 on which a non-conductive film (NCF) or an anisotropic conductive film (ACF) 232 is formed is then prepared in the second embodiment of the disclosure. Driving board electrodes 31 are formed on the driving circuit board 30.

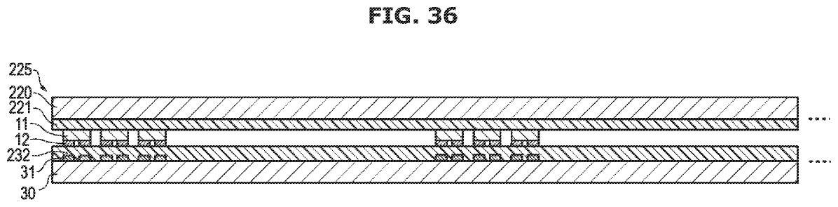

And then, in the second embodiment of the disclosure, as shown in FIG. 36, the temporary holding board 225, on which the micro LED chips 11 are transferred, is positioned to face the driving circuit board 30, on which the NCF or ACF 232 is formed, so that the LED electrodes 12 and the driving board electrodes 31 are overlapped each other, and then pressed.

As a result, the micro LED chips 11 are held on the driving circuit board 30 through the NCF or ACF 232. And then, the driving circuit board 30 on which the micro LED chips 11 are held is heated in the second embodiment of the disclosure as in first embodiment of the disclosure. In the second embodiment of the disclosure, the heating makes the LED electrodes 12 electrically connected to the driving board electrodes 31 through the NCF or ACF 232.

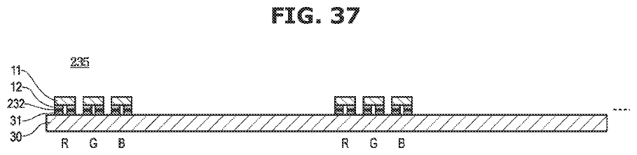

FIG. 37 is a cross-sectional view illustrating a finished display module, according to the second embodiment of the disclosure.

Subsequently, in the second embodiment of the disclosure, cleansing is performed after the temporary holding board 225 is removed, as shown in FIG. 37. The display module 235 is then completed.

As described above, in the second embodiment of the disclosure, the source board 325, which is an intermediate structure, is manufactured, the micro LED chips 11 are transferred onto the temporary holding board 225 from the source board 325, and then the micro LED chips 11 are collectively transferred onto the driving circuit board 30. Also, in the second embodiment of the disclosure as in the first embodiment of the disclosure, accuracy in chip transfer position is improved, and a time to manufacture a display may be reduced as compared to an occasion when the source board 325 is not manufactured.

An example of manufacturing a display module for testing will now be described.

A first example is obtained by test-manufacturing according to the first embodiment of the disclosure.

In the first example, the micro LED chips 11 were manufactured on the sapphire substrate 100 of 6 inches (see FIGS. 1 and 2).

In the first example, polyimide HD3007 (manufactured by HD Microsystems®) was applied on the sapphire substrate 100 by spin coating, pre-baked for 3 minutes at 120° C., and then cured for 1 hour at 250° C. After curing, the thickness of the polyimide was about 10 μm (see FIG. 3).

Subsequently, in the first example, the sapphire substrate 100 and a quartz glass substrate corresponding to the supporting substrate 14 were joined and bonded with a load of 2000 N for 10 minutes at 300° C. (see FIG. 4).

In the first example, a lift-off treatment was performed by irradiating excimer laser having a wavelength of about 248 nm to the entire surface from a side of the sapphire substrate 100 (see FIG. 5), to separate the micro LED chips 11 from the sapphire substrate 100 (see FIG. 6).

Subsequently, in the first example, an oxygen plasma RIE treatment was performed on the micro LED chips 11 to remove the polyimide between the chips, the result of which was the donor board 15 (see FIG. 7).

In the first example, the laser-light transparent substrate 20 (a quartz glass substrate) was first prepared as a base of the source board 25, and the first resin layer 21 was formed on the laser-light transparent substrate 20. The first resin layer 21 was applied by spin coating. For the first resin layer 21, polyimide HD3007 (manufactured by HD Microsystems®) was used. For spin coating, the number of revolutions and time were adjusted for a desirable thickness.

In the first example, after the spin coating, a pre-bake treatment was performed to heat and preliminarily dry the first resin layer 21 for 3 minutes at 120° C. The first resin layer 21 was then heated for 1 hour at 250° C. in an oven. As a result, in the first example, the first resin layer 21 having a thickness of about 1 μm was formed on the laser-light transparent substrate 20 (see FIG. 8).

Subsequently, in the first example, the second resin layer 22 was applied on the first resin layer 21 by spin coating. For spin coating, the number of revolutions and time were adjusted for a desirable thickness. In the first example, after the spin coating, a pre-bake treatment was performed to heat the second resin layer 22 for 3 minutes at 120° C. to dry and remove a solvent. As a result, in the first example, the second resin layer 22 having a thickness of about 5 μm was formed (see FIG. 9). The second resin layer 22 was formed by applying a diluted coating solution obtained by adding SEPTON2063 (manufactured by Kuraray®) to toluene to be 5 mass % and agitating them.

Subsequently, in the first example, with the first laser transfer process, the micro LED chips 11 were transferred onto the second resin layer 22 from respective ones of the donor board 15, that are R, G, and B donor boards, at desired pitches (see FIGS. 10 to 15). In the first example, in the first laser transfer process, the laser light 110 in the form of a line was irradiated to continuously transfer the micro LED chips 11 of respective colors.

Then in the first example, the resin layer for donor 13 on the micro LED chips 11 and the first resin layer 21 and the second resin layer 22 between chips were removed by dry etching. The dry etching was performed with RIE based on oxygen plasma. In this case, the polyimide left on the LED electrodes 12 after the first laser process was also etched, so that the polyimide was completely removed.

As a result, in the first example, the source board 25 (intermediate structure), on which the micro LED chips 11 of different colors were arranged in desired positions, was completed (see FIG. 16).

In the first example, micro solder bumps 32 were formed on the driving circuit board 30 on which the driving board electrodes 31 were formed. The micro solder bumps 32 were formed by connecting them to Cu pads of the driving circuit board 30. The micro solder bumps 32 were formed using Ni 0.5 μm/SAC (SnAgCu, Ag 3%, Cu 0.5%) 1 μm.

Subsequently, in the first example, the flux 33 was applied by spraying to have a thickness of about 10 μm on the driving circuit board 30 on which the micro solder bumps 32 were formed (see FIG. 17).

Then in the first example, the source board 25 was positioned to face the driving circuit board 30 to which the flux 33 was applied so that a set of three of the micro LED chips 11, that are R, G, and B micro LED chips, were positioned to overlap the micro solder bumps 32 of the driving circuit board 30.

A laser ablation treatment was then performed in the first example as a second laser transfer process (see FIG. 18), so that the micro LED chips 11 were transferred to positions overlapping the micro solder bumps 32 on the flux 33 of the driving circuit board 30.

Subsequently, in the first example, 230° C. heating is performed using a reflow oven so as to volatilize the flux 33 and melt the micro solder bumps 32 to be metal joined with the LED electrodes 12 (see FIG. 19).

Furthermore, in the first example, the driving circuit board 30 on which the micro LED chips 11 were mounted was soaked in xylene for 3 minutes to swell and dissolve the first resin layer 21 left on the micro LED chips 11.

Subsequently, in the first example, the driving circuit board 30 on which the micro LED chips 11 were mounted was showered and cleansed with a flux cleansing liquid based on a alkaline solution. Accordingly, remnants of the first resin layer 21 and the second resin layer 22 and the flux 33 left on the micro LED chips 11 were removed.

Furthermore, in the first example, the driving circuit board 30, from which the first resin layer 21 and the second resin layer 22 were removed, sequentially went through rinsing by pure water shower, dehydration with an air knife, and baking by drying for 2 minutes at 135° C. with a hotplate.

As a result, in the first example, the display module 35 with the micro LED chips 11 solder-mounted on the driving circuit board 30 was completed (see FIG. 20).

In a second example, the micro LED chips 11 were manufactured on the sapphire substrate 100 of 6 inches as in the first example (see FIG. 25).

Subsequently, in the second example, the relay substrate 214 having the temporary holding layer 213 was prepared, and the micro LED chips 11 were held on the relay substrate 214. The temporary holding layer 213 was formed using PDMS of a thickness of about 10 μm.

Subsequently, in the second example, the sapphire substrate 100 was removed by separating the micro LED chips 11 from the sapphire substrate 100 by a laser lift-off method (see FIG. 26), and the micro LED chips 11 were held on the temporary holding layer 213.

Then in the second example, as the resin layer for donor 13, a polyimide resin was formed into a thickness of about 5 μm on the supporting substrate 14 formed of the quartz glass substrate. The relay substrate 214 was bonded to the supporting substrate 14 on which the resin layer for donor 13 was formed (see FIG. 27).

Subsequently, in the second example, the micro LED chips 11 were held on the resin layer for donor 13 (a polyimide resin) by removing the relay substrate 214.

Also in the second example, the polyimide resin between the chips were removed by an RIE treatment to complete the donor board 215 (see FIG. 29) as in the first example. Unlike in the first example, the LED electrodes 12 on the micro LED chips 11 formed on the donor board 215 were exposed in the second example.

Subsequently, in the second example, the first resin layer 21 and the second resin layer 22 were formed on the laser-light transparent substrate 20 (a quartz glass substrate), which is a base of the source board 325 (see FIG. 30) as in the first example. Then in the second example, the micro LED chips 11 were transferred onto the laser-light transparent substrate 20 by a laser ablation treatment that irradiates the laser light 110 from a side of the relay substrate 214 as in the first example. After this, in the second example, an RIE treatment was performed (see FIGS. 31 to 33).

As such, in the second example, the source board 325 on which the micro LED chips 11 are arranged in the opposite direction of the first example was completed.

In the second example, to bond the micro LED chips 11 (that are R, B, G, micro LED chips) collectively with the driving circuit board 30, first, a laser ablation treatment was performed on the temporary holding board 225 (see FIG. 34). For the temporary holding board 225, the quartz glass substrate 220 with 5 μm thick PDMS formed thereon as the temporary holding layer 221 was used.

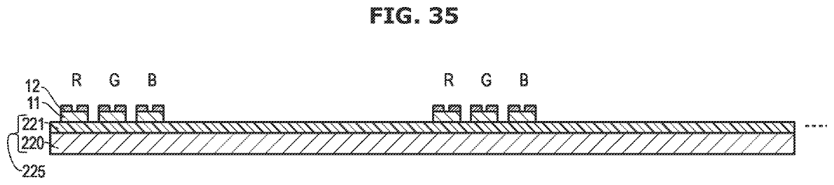

Subsequently, in the second example, the micro LED chips 11 were transferred onto the temporary holding board 225 from the source board 325. The RIE treatment was then performed to completely remove the first resin layer 21 and the second resin layer 22 left on the electrodes of the micro LED chips 11 in the second example (see FIG. 35).

Next, the driving circuit board 30 with the driving board electrodes 31 arranged thereon were prepared and laminated with the NCF or ACF 232 in the second example.

Subsequently, in the second example, the driving circuit board 30 is positioned to face the temporary holding board 225, onto which the micro LED chips 11 were transferred, so that the driving board electrodes 31 overlap the LED electrodes 12.

And then, the driving circuit board 30 was pressed to the temporary holding board 225 with a load of 1000 kgf, so that the micro LED chips 11 were held on the NCF or ACF 232 on the driving circuit board 30 (see FIG. 36), in the second example. After this, in the second example, the temporary holding board 225 was removed, and the driving circuit board 30 on which the micro LED chips 11 were held was cleansed.

As a result, in the second example, the display module 235 with the micro LED chips 11 mounted on the driving circuit board 30 was completed (see FIG. 37).

Various modifications and changes to the non-limiting example embodiments of the disclosure may be made without deviating from the scope of the disclosure.

What is claimed is:

1. An intermediate structure for manufacturing a micro light emitting diode (LED) display, the intermediate structure comprising:
a transparent substrate that is configured to allow laser light of a certain wavelength to be transmitted there through;
a first resin layer arranged on the transparent substrate;
a second resin layer arranged on the first resin layer; and
a plurality of micro LED chips arranged on the second resin layer,
wherein the first resin layer and the second resin layer are patterned to correspond to the plurality of micro LED chips.

2. The intermediate structure of claim 1, wherein the first resin layer and the second resin layer are configured to be oxygen plasma based dry etched.

3. The intermediate structure of claim 2, wherein the first resin layer is configured to be decomposed by a laser ablation treatment.

4. The intermediate structure of claim 3, wherein the first resin layer comprises at least one resin material selected from a group consisting of a polyimide resin, an acrylic resin, an epoxy resin, a polypropylene resin, a polycarbonate resin, and an acrylonitrile butadiene styrene (ABS) resin.

5. The intermediate structure of claim 2, wherein the second resin layer comprises a resin material having compressive modulus of about 1 to 100 Mpa.

6. The intermediate structure of claim 5, wherein the resin material or at least one other resin material of the second resin layer is selected from a group consisting of urethane, isoprene, and butadiene.

7. The intermediate structure of claim 1, wherein the transparent substrate is configured to transmit 50% or more of laser light with a wavelength of 248 to 355 nm.

8. The intermediate structure of claim 3, wherein the first resin layer is configured to absorb 60% or more of laser light of 248 to 355 nm.

9. The intermediate structure of claim 1, wherein the first resin layer has a thickness of 0.5 to 2 μm.

10. The intermediate structure of claim 1, wherein the second resin layer has a thickness of 1 to 10 μm.

11. The intermediate structure of claim 1, wherein the plurality of micro LED chips comprise micro LED chips of different light emitting colors,
wherein the plurality of micro LED chips are arranged on the second resin layer in a form of a matrix, and
wherein each of the plurality of micro LED chips constitutes a subpixel of the micro LED display.

12. A method of manufacturing an intermediate structure for manufacturing a micro light emitting diode (LED) display, the method comprising:
stacking a first resin layer on a transparent substrate, the transparent substrate configured to transmit laser light of a certain wavelength;
stacking a second resin layer on the first resin layer;
arranging a plurality of micro LED chips on the second resin layer; and
patterning the first resin layer and the second resin layer to correspond to the plurality of micro LED chips.

13. The method of claim 12, wherein the patterning of the first resin layer and the second resin layer comprises patterning the first resin layer and the second resin layer using oxygen plasma dry etching.

14. The method of claim 12, wherein the first resin layer comprises at least one resin material selected from a group consisting of a polyimide resin, an acrylic resin, an epoxy resin, a polypropylene resin, a polycarbonate resin, and an acrylonitrile butadiene styrene (ABS) resin.

15. The method of claim 12, wherein the second resin layer comprises at least one resin material selected from a group consisting of urethane, isoprene, and butadiene.

16. The method of claim 12, wherein the arranging of the plurality of micro LED chips comprises arranging the plurality of micro LED chips on the second resin layer in a form of a matrix such that each of the plurality of micro LED chips forms a subpixel of the micro LED display.

17. A method of manufacturing a micro light emitting diode (LED) display, the method comprising:
manufacturing an intermediate structure by:
stacking a first resin layer on a transparent substrate, the transparent substrate configured to transmit laser light of a certain wavelength;
stacking a second resin layer on the first resin layer;
arranging a plurality of micro LED chips on the second resin layer; and
patterning the first resin layer and the second resin layer to correspond to the plurality of micro LED chips; and
transferring at least one group of micro LED chips, from among the plurality of micro LED chips, from the intermediate structure to a driving circuit board of the micro LED display.

18. The method of claim 17, wherein the transferring comprises transferring the at least one group of micro LED chips by irradiating the laser light.

19. The method of claim 17, wherein the patterning of the first resin layer and the second resin layer comprises patterning the first resin layer and the second resin layer using oxygen plasma dry etching.

20. The method of claim 17, wherein each micro LED chip from among the at least one group of micro LED chips forms a subpixel of the micro LED display.
